(19) United States
(12) Patent Application Publication
(10) Pub. No.: US 2008/0257264 A1
(43) Pub. Date: Oct. 23, 2008

(54) FACILITY FOR DEPOSITING LUBRICANT COATING ON HARD MAGNETIC DISKS

(75) Inventor: Carl Petersen, Fremont, CA (US)

Correspondence Address: NIXON PEABODY, LLP, 401 9TH STREET, NW, SUITE 900, WASHINGTON, DC, 20004-2128, US

(73) Assignee: INTEVAC CORPORATION, Santa Clara, CA (US)

(21) Appl. No.: 11/737,807

(22) Filed: Apr. 20, 2007

(51) Int. Cl. C23C 16/00

(52) U.S. Cl. 118/723 VE

(57) ABSTRACT

A facility for depositing lubricant coatings on hard magnetic disks includes load and unload vacuum locks in which cassettes carrying hard magnetic disks to be coated with a lubricant coating are turned 90°. Lubricant coatings are simultaneously deposited on a plurality of hard magnetic disks in a process module. Plural cassettes carrying the hard magnetic disks are simultaneously located in the load and unload vacuum locks. Plural cassettes carrying the hard magnetic disks are simultaneously located in a buffer zone between a load vacuum lock and the module for depositing the lubricant coatings.

### FIELD OF THE INVENTION

The present invention relates generally to a facility for depositing lubricant coatings on hard magnetic disks, and more particularly to such a facility including a path traversed by cassettes carrying hard magnetic disks to be coated with a lubricant coating that is derived from vapor, wherein the path has at least one 90° turn. A further aspect of the invention relates to a facility for depositing lubricant coatings on hard magnetic disks, wherein the facility includes an arrangement for substantially simultaneously depositing, in a vacuum environment, lubricant coatings on a plurality of hard magnetic disks. An additional aspect of the invention relates to a facility for vacuum depositing lubricant coatings on hard magnetic disks, wherein plural cassettes carrying the hard magnetic disks are simultaneously located in load and/or unload vacuum locks. An added aspect of the invention relates to a facility for vacuum depositing lubricant coatings on hard magnetic disks, wherein plural cassettes carrying the hard magnetic disks are simultaneously located in a buffer zone between a load vacuum lock and a module for depositing vapor lubricant coatings on the hard magnetic disks. Another aspect of the invention relates to a facility for depositing lubricant coatings on hard magnetic disks, wherein the features previously set forth in this paragraph are combined.

### BACKGROUND ART

Hughes et al., U.S. Pat. No. 6,183,831 (incorporated by reference herein) discloses a facility for coating hard magnetic disks with a lubricant film by applying a lubricant in vapor (that is, gaseous) form to a magnetic layer on the disks in a vacuum environment. The lubricant is preferably a perfluoropolyether (PFPE) as disclosed in U.S. Pat. No. 5,776,577. The hard magnetic disks are loaded into cassettes that are conveyed into and out of the vacuum environment via a load lock and an unload block, respectively. The vacuum environment includes a single processing chamber in which a single magnetic disk is coated with the lubricant vapor. The disc is coated on both sides during a single processing interval. The single processing chamber includes a lift blade for lifting the hard magnetic disks from the cassettes into a portion of the processing chamber where the disks are exposed to the lubricant vapor. After the coating operation has been completed, the lift blade returns the hard magnetic disk to the cassette from which the hard magnetic disk was originally lifted. The single processing chamber in which the single magnetic disk is coated with lubricant vapor is downstream of a 12 station carousel sputtering tool. After all the disks in a particular cassette have been coated with lubricant, the cassette passes through an unload gate into an unload lock, to complete the process.

The foregoing arrangement described in the Hughes et al. patent has performed satisfactorily, but can be improved. The throughput processing rate and spatial footprint of the facility described in the Hughes et al. patent can be increased and decreased, respectively. In addition, there are instances where it is desirable for the facility for depositing the lubricant film onto the hard magnetic disks to be a stand alone unit that is separate from the remainder of the facility for forming a complete hard magnetic disk.

### SUMMARY OF THE INVENTION

The present invention includes several features, each including a facility for depositing lubricant coatings on hard magnetic disks that are adapted to be loaded in cassettes. The facility comprises an arrangement for conveying the cassettes through a path including a vacuum load lock and a vacuum unload lock. The path also includes a vacuum process module that is between the vacuum load and unload locks and deposits lubricant vapor on the hard magnetic disks, wherein the deposited lubricant vapor forms a lubricant coating on the hard magnetic disks.

According to one of the features, the path is arranged for turning the cassettes approximately 90°, at least once and preferably twice. Preferably, both the vacuum load and unload locks turn the cassettes approximately 90°, to assist in providing a facility having a small footprint, although it is to be understood that only the load or unload lock can be so arranged or that the turning arrangement can be somewhere else in the path.

According to another of the features, the path includes plural vacuum process modules for substantially simultaneously depositing lubricant vapor onto plural hard magnetic disks initially loaded into a plurality of the cassettes. By substantially simultaneously depositing lubricant onto plural hard magnetic disks, throughput rate is relatively high.

A further of the features is that at least one of the load and unload locks is arranged for enabling a plurality of the cassettes to be simultaneously between entrance and exit regions thereof. Preferably both the load and unload locks are arranged for enabling a plurality of the cassettes to be simultaneously between the entrance and exit regions thereof, to assist in increasing throughput rate. It is to be understood, however, that only the load or unload lock can be so arranged.

An additional one of the features is that the path has a buffer region between the exit region of the load lock and the process module, wherein the buffer region is arranged for enabling a plurality of the cassettes to be simultaneously therein. A buffer region that enables plural cassettes to be simultaneously therein assists in increasing throughput rate.

Preferably, to provide high throughput and a small footprint, the facility is such that the buffer region is arranged for enabling two and not more than two of the cassettes to be simultaneously therein, and the load lock includes first and second valves respectively at entrance and exit regions of the load lock, while the unload lock includes third and fourth valves respectively at entrance and exit regions of the unload lock. The load lock is arranged for enabling two cassettes to be simultaneously between the first and second valves, and the unload lock is arranged for enabling two cassettes to be simultaneously between the third and fourth valves. The vacuum load and unload locks are arranged for turning the cassettes approximately 90°. The facility includes two process modules arranged for simultaneously depositing lubricant vapor onto two hard magnetic disks.

A very small footprint is achieved by shaping the facility, in plan view, approximately as a U having first and second parallel, substantially equal length legs connected together by a base that is at right angles to the first and second parallel legs. The first and second legs respectively include the load and unload locks and the base includes the buffer region and the two process modules. The spacing between the legs and the lengths of the legs are sufficient to form an operator area within the U for enabling an operator (a) to gain proximity to the process module located in the base for maintenance and service work, (b) to load cassettes with hard magnetic disks therein onto the conveyor arrangement at a portion of the first leg in proximity to the end of the first leg remote from the base, and (c) to remove cassettes with hard magnetic disks that have been coated in the process modules from the conveyor arrangement at a portion of the second leg in proximity to the end of the second leg remote from the base.

The above and still further objects, features and advantages of the present invention will become apparent upon consideration of the following detailed description of a specific embodiment thereof, especially when taken in conjunction with the accompanying drawings.

### BRIEF DESCRIPTION OF THE DRAWINGS

FIG. 1 is a perspective view of a stand-alone facility for depositing lubricant (lube) vapor onto hard magnetic disks in cassettes that are transported through a path in the facility, in accordance with a preferred embodiment of the invention;

FIG. 2 is a plane view of the facility illustrated in FIG. 1, wherein covers over the load and unload locks, and a buffer module, are removed;

FIG. 3 is a perspective view of the load lock and unload lock in the facility of FIG. 2;

FIG. 4 is an exploded view of the structure illustrated in FIG. 3;

FIG. 5 is a perspective view of a portion of the structure illustrated in FIG. 3;

FIG. 6 is an exploded view of the structure illustrated in FIG. 5;

FIG. 7 is a perspective view of a portion of the buffer lock of FIG. 2;

FIG. 8 is an exploded view of the structure illustrated in FIG. 7;

FIG. 9 is a perspective view of the process modules illustrated in FIGS. 1 and 2;

FIG. 10 is an exploded view of the structure illustrated in FIG. 9;

FIG. 11 is a perspective view of a transport segment of one of the process modules of FIGS. 9 and 10; and

FIG. 12 is an exploded view of the structure illustrated in FIG. 11.

### DETAILED DESCRIPTION OF THE DRAWINGS

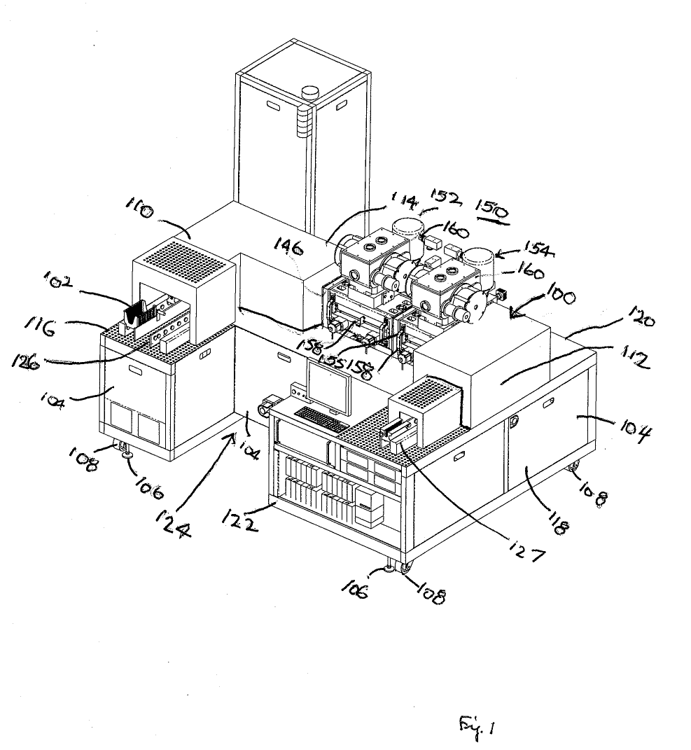

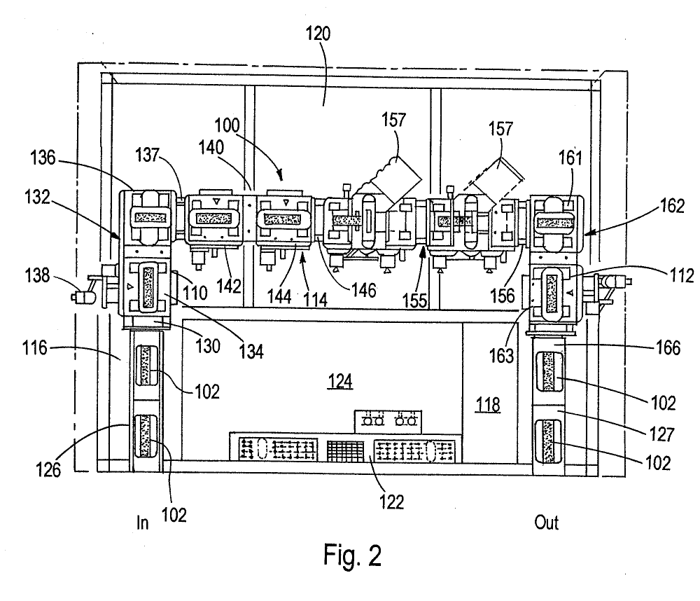

Reference is now made to FIGS. 1 and 2 wherein freestanding facility 100 for vapor depositing lubricant coatings on hard magnetic disks in cassettes, such as cassettes 102, is placed on the conveyer 126 which, upon detecting the presence of the cassette, transports the cassettes 102 into one of the parallel legs of the facility 110. Cabinets 104, in which the controllers for the conveyer 126 are mounted have feet 106 that are adjustable in height to assure flatness of facility 100 and casters 108 for enabling the cabinets and facility to be moved without too much difficulty.

In plan view, as illustrated in FIG. 2, facility 100 is shaped approximately as a U including two parallel legs 110 and 112 connected together by base 114. Cabinets 104 also include two parallel legs 116 and 118, connected together by base 120 on which are fixedly mounted legs 110 and 112, and base 114, respectively. At the end of leg 118 remote from base 120, cabinets 104 include appendage 122 that extends parallel to base 120.

The end of appendage 122 remote from leg 118 is spaced from leg 116 to provide an opening for enabling an operator to enter operator area 124, within the 72″×96″ rectangular footprint formed by the exterior walls of cabinets 104. The operator, while within operator area 124, loads cassettes carrying hard magnetic disks, to be coated with a lubricant film in facility 100, onto a motor driven roller conveyor arrangement 126, that extends between facility 100 and the end of leg 116 remote from base 120. A similar motor driven roller conveyor 127 extends between facility 100 and the end of leg 118 remote from base 120. Appropriate conveyor arrangements are available from Stratus Automation Corp. Kent, Wash. The operator, while within operator area 114, loads the cassettes onto a portion of conveyor arrangement 126 at the end of leg 116 remote from base 120. The operator, while within operator area 124, unloads, from conveyor arrangement 127, cassettes including hard magnetic disks that have been vapor coated with lubricant in facility 100, with the unloading occurring at the end of leg 118 remote from base 120.

After cassettes 102 have been loaded onto the portion of conveyor arrangement 126 at the end of leg 116 remote from base 120, the conveyor arrangement transports the cassettes through open solenoid activated gate valve 130 into the entrance end of load lock 132. Load lock 132 includes first and second sections 134 and 136 that are connected to each other, without the intermediary of a gate valve, so that the same pressure is in both sections. Each of sections 134 and 136 includes a motor driven roller conveyor. While gate valve 130 is open and cassettes 102 are being loaded into sections 134 and 136, solenoid activated gate valve 137 at the exit end of load lock 132, is closed. Each of sections 134 and 136 is long enough to enable only a single cassette 102 to be located therein, so that two of the cassettes are simultaneously in load lock 132. After two of the cassettes 102 have been simultaneously loaded in load lock 132, gate valve 130 is closed. Then vacuum pump 138, mounted on load lock 132, reduces the pressure in the load lock 132 from atmospheric pressure to a suitable vacuum pressure for transporting the cassettes 102 to the buffer module 140.

Section 136 of load lock 132 includes a 90° turntable with a motor driven roller conveyor, such as a turntable available from Stratus Automation Corp. The turntable in section 136 turns the longitudinal axes of cassettes 102 loaded into section 136 90°. Hence, the turntable turns the longitudinal axes of cassettes 102 from alignment with the longitudinal direction of leg 110 to alignment with the longitudinal direction of base 114. The conveyor on the turntable in section 136 is longitudinally aligned with the conveyor in section 134 while gate valve 130 is open and two cassettes are being loaded by conveyor arrangement 126 into load lock 132.

After the conveyor arrangement 126 has driven first and second cassettes 102 into sections 134 and 136, respectively, and gate valves 130 and 137 have been closed and while pump 138 is pumping out load lock 132, the turntable in section 136 is turned 90° in a first direction. After the suitable vacuum pressure has been achieved in load lock 132 and the cassette 102 initially in section 136 has been turned 90°, gate valve 137 is open and the portion of conveyor arrangement 126 in section 136 moves the cassette initially in section 136 through gate valve 137. Then the turntable in section 136 is turned 90° in a second direction (opposite to the first direction) so that the longitudinal axis of the conveyor portion in section 136 is again aligned with the longitudinal axis of the conveyor portion in section 134. Then the cassette 102 initially in section 134 is moved by the conveyor portions in sections 134 and 136 into section 136. The turntable in section 136 then turns 90° in the first direction, to turn the longitudinal axis of the cassette initially in section 134 90° so it is aligned with the longitudinal axis of base 114. The conveyor in section 136 then longitudinally moves the cassette initially in section 134 through gate valve 137. Then gate valve 137 is closed and the turntable is turned 90° in the second direction, followed by opening of gate valve 130. With gate valve 130 open and gate valve 137 closed, two additional cassettes are loaded into load lock 132 and the foregoing procedure is repeated.

The two cassettes 102, after having passed through gate valve 137, are in vacuum buffer module 140, having two aligned, identically constructed sections 142 and 144 that are connected together. Sections 142 and 144 are connected to each other, without the intermediary of a gate valve, so that the same vacuum pressure is in both sections. Each of sections 142 and 144 includes a solenoid activated rough valve, connected to a vacuum pump that reaches a suitable vacuum pressure in buffer module 140, enabling the lubricant vapor to be coated on the hard magnetic disks in cassettes 102. Each of sections 142 and 144 also includes a motor driven roller conveyor. While gate valve 137 is open and the cassettes 102 previously in load lock 132 are moved into buffer module 140 by the conveyors in load lock 132 and buffer module 140, solenoid activated gate valve 146, at the exit end of buffer module 140, is closed. Each of sections 142 and 144 is long enough to enable a single cassette 102 to be located therein, so that two of the cassettes are simultaneously in buffer module 140. After conveyor arrangement 126 has loaded two of the cassettes 102 in buffer module 140, so that a first of the cassettes is in section 142 and a second of the cassettes is in section 144, gate valve 137 is closed. When process module 150 is ready to receive the magnetic hard disks in the cassettes in buffer module 140, gate valve 146 is open and the conveyors in buffer module 140 and process module 150 transport the two cassettes into process module 150.

Process module 150 includes two aligned, identically constructed sections 152 and 154 that are connected together. Sections 152 and 154 are connected to each other. Sections 152 and 154 are connected to each other through the intermediary of solenoid activated gate valve 155, so that processing of magnetic hard disks in section 152 does not affect processing of disks in section 154, and vice versa. To assist in maintaining a suitable vacuum pressure in each of sections 152 and 154, each section carries a separate vacuum pump 157 that is connected directly to a chamber within each of the sections, without the intermediary of a valve.

Each of sections 152 and 154 includes a motor driven roller conveyor. While gate valve 146 is open and the conveyors in buffer module 140 and process module 150 are loading first and second cassettes into sections 152 and 154 respectively, solenoid activated gate valve 156, at the exit end of process module 150, is closed. Each of sections 152 and 154 is long enough to enable two cassettes 102 to be located therein at the same time. During coating of the discs, two cassettes 102 are never simultaneously located in either of sections 152 or 154, although two of the cassettes are simultaneously in process module 150. After two of the cassettes 102 have been loaded in process module 150, so that a first of the cassettes is in section 152 and a second of the cassettes is in section 154, gate valves 146 and 156 are closed.

Each of sections 152 and 154 includes a transport segment 158 and a process segment 160. Each of the transport segments 158 includes (1) a motor driven roller conveyor for transporting the cassettes through the particular section 152 or 154, and (2) a solenoid activated lift blade assembly for separately lifting each of the magnetic hard disks in the cassettes in a particular section into process segment 160 of that section. Each process segment 160 can be constructed in accordance with the disclosure in the aforementioned U.S. Pat. No. 6,183,831, but is preferably constructed in accordance with the disclosure in the co-pending, commonly assigned application of Petersen et al., Ser. No. 11/693,039, filed Mar. 29, 2007, entitled Apparatus for and Method of Applying Lubricant Vapor to Hard Magnetic Disks Via a Vapor Flow Path Including a Selectively Opened and Closed Shutter, the disclosure of which is incorporated herein by reference.

After the lift blade assemblies in sections 152 and 154 have separately lifted a magnetic hard disk in each of sections 152 and 154 from the cassettes in these sections into the process segments 160 of these sections and the hard disks are stationary and in place in the process segments 160, the process segments 160 of sections 152 and 154 are activated to coat vapor lube films onto the magnetic hard disks in the two process segments of sections 152 and 154. Consequently, lube films can be applied simultaneously or approximately simultaneously to the two different magnetic hard disks that have been lifted into place in process segments 160 of sections 152 and 154.

After the magnetic hard disk has been processed in process segment 160 of a particular section 152 or 154, the lift blade assembly in the particular section returns the processed magnetic hard disk to the cassettes resident in the particular section. Then, the conveyor arrangement in the particular section moves the cassette in the particular section forward in transport segment 158 of the particular section so that the next magnetic hard disk in the cassette is above the lift blade of the particular section. The next magnetic hard disk is then lifted from the cassette into the process segment 160 of the particular section and the process is repeated until all the magnetic hard disks in a particular cassette have been coated.

After all the magnetic hard disks in the cassettes in sections 152 and 154 have been coated with lube films, the front, that is leading, edges of the cassettes in sections 152 and 154 are next to closed gate valves 155 and 156, respectively. At this time, gate valve 146 between buffer module 140 and process module 150 is closed. Then, gate valves 155 and 156 are opened and the conveyor arrangement in section 154 transports the cassette that was processed in section 154 into section 161 of unload lock 162, while the conveyor arrangements in sections 152 and 154 transport the cassette that was processed in section 152 into section 154. The cassette that was processed in section 154 quickly moves through section 161 of unload lock 162 and the cassette that was processed in section 152 then quickly moves from section 154 into section 161 of unload lock 162, without section 154 processing the discs previously processed in section 152.

After the cassette that was processed in section 152 has been moved into section 161 of unload lock 162, gate valve 156 is closed, and then gate valve 146 is opened, while gate valve 155 remains open. Then the conveyors in modules 140 and 150 move the two cassettes that were idling in buffer module 140 into process module 150, and the process is repeated.

Unload lock 162 is constructed identically to load lock 132, except that the turntable and valves in unload lock 162 operate in a reverse manner from load lock 132. Thus, unload lock 162 includes section 163, as well as section 161 where the 90° turn table is located. Solenoid activated exit gate valve 166 is at the end of section 163 remote from base 114 of facility 100.

In operation, after the cassette that was processed in section 154 has passed from section 154 through gate valve 156 into section 161 and has been turned 90° in a first direction by the turntable in section 161 and then transported into section 163, the turntable in section 161 is turned 90° in a second opposite direction and the cassette that was processed in section 152 is transported through gate 156 onto the turntable in section 161. Then gate valve 156 is closed and the turntable in section 161 is turned 90° in the first direction so that the cassettes in sections 161 and 163 are aligned and the longitudinal axes thereof extend in the same direction as leg 112. Then gate valve 166 is opened and the cassettes in unload lock 162 are transported to conveyor segment 127 on leg 118 of the cabinet arrangement. The operator removes the cassettes from conveyor segment 127, and then removes the finished magnetic hard disks from the cassettes, that are reused.

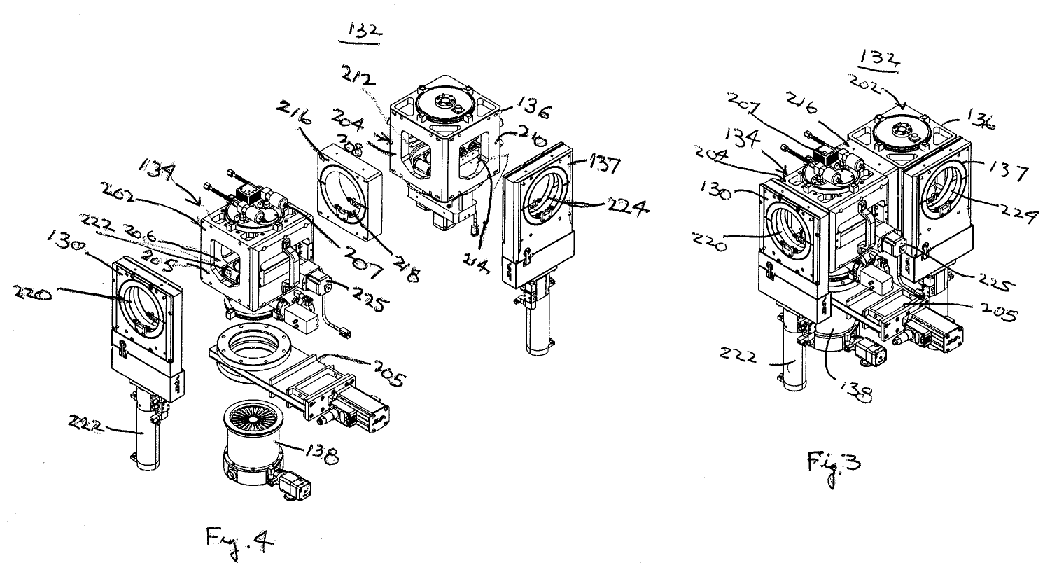

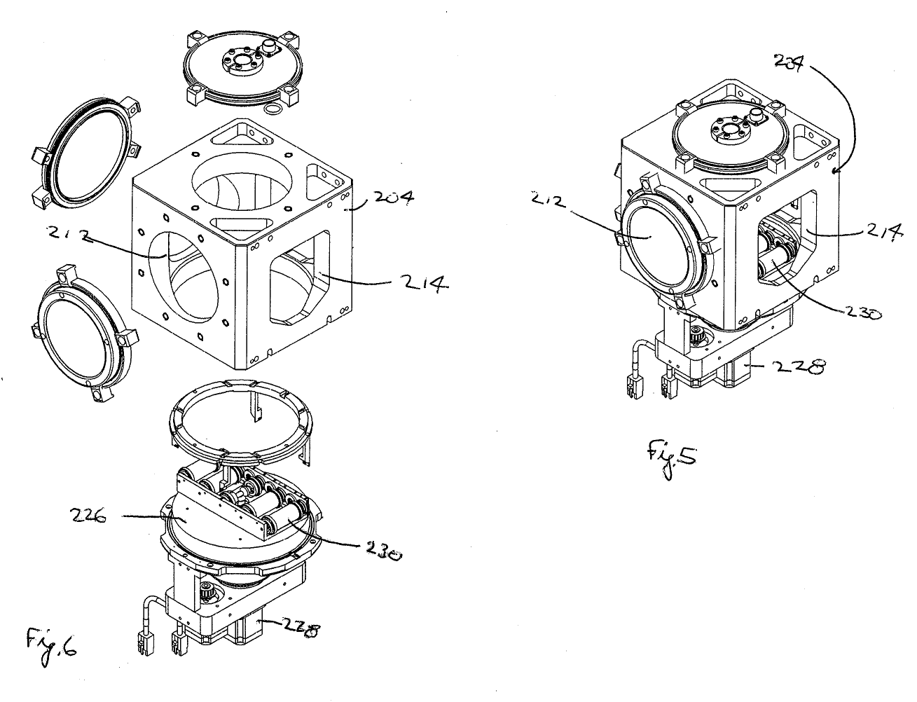

Reference is now made to FIGS. 3-6, wherein FIGS. 3 and 4 are respectively perspective and exploded perspective views of load lock 132 and FIGS. 5 and 6 are respectively perspective and exploded perspective views of section 136 of load lock 132. Sections 134 and 136 respectively include metal, cube shaped housings 202 and 204. The floor of housing 202 includes a passage (not shown) that is selectively coupled to high vacuum turbo pump 138 by solenoid activated high vacuum valve 205. Valve 205 is controlled by pressure sensor arrangement 207 on the roof of housing 202.

Housing 202 includes a pair of parallel walls 205 (only one of which is illustrated) in which are located aligned apertures 206 (only one of which is illustrated) through which cassettes 102 pass, while housing 204 includes walls 208 and 210 that are at right angles to each other and respectively include apertures 212 and 214 through which the cassettes pass. Spacer 216, including aperture 218, is between and abuts the adjacent and parallel walls 205 and 208 of housings 202 and 204. Apertures 206, 212 and 218 are aligned with each other and with aperture 220 in gate valve 130 when the gate valve 130 is open to enable the cassettes to be transported by motor driven conveyor rollers 222 in the bottom of housing 202 through the open aperture 220 into housing 204. Rollers 222 are driven by motor 225, carried by housing 202. Aperture 220 is selectively opened and closed by a solenoid (not shown) in stem 222 driving a shutter (not shown) up and down relative to aperture 220. Gate valve 137, constructed identically to gate valve 130, includes aperture 224 that is aligned with aperture 214 in wall 210 of housing 204.

The floor of housing 204 includes turntable 226 that is turned clockwise and counterclockwise about a vertical axis through 90° by motor 228, carried by housing 204. Turntable 226 carries conveyor rollers 230 that are driven by motor 228. A clutch arrangement (not shown) enables motor 228 to drive turntable 226 and rollers 230 at mutually exclusive times, as is necessary because the cassettes in housing 204 are always driven longitudinally and turned at mutually exclusive times. Motor 228 and the clutch connected to it are controlled by position sensor arrangement 232 mounted on the ceiling of housing 204.

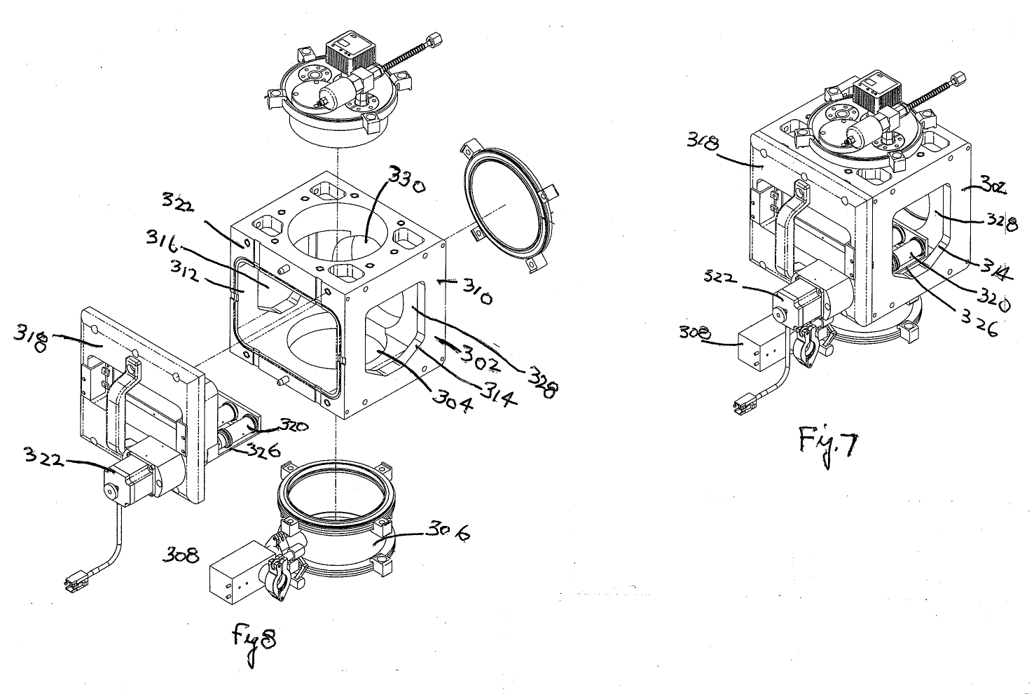

Reference is now made to FIGS. 7 and 8, respectively perspective and exploded perspective views of section 142 of buffer module 140. Because sections 142 and 144 of buffer module 140 are identical only section 142 is illustrated and described.

Section 142 includes metal, cube shaped housing 302, the floor of which includes passage 304 that is connected to rough valve 306, in turn selectively connected to a low-speed vacuum pump (not shown). Rough valve 306 includes a shutter (not shown) that is selectively opened and closed by solenoid 308. Generally, the shutter of valve 306 remains open and the interior of housing 302 is usually maintained in a vacuum condition. The shutter of valve 306 is closed for maintenance of section 142.

Housing 302 includes parallel walls 310 and 312 in which are respectively located aligned apertures 314 and 316, through which the cassettes 102 pass. Panel 318 carries conveyor rollers 320 and motor 322, that drives the conveyor rollers. Panel 318 is fixedly mounted on wall 324 that it is between and at a right angle to walls 310 and 312. Panel 318 fits over rectangular opening 324 in wall 322, causing rollers 320 and channel 326, that captures the rollers and is carried by panel 318, to be fixedly mounted within the interior of housing 302.

Housing 302 also includes wall 328, which is parallel to wall 322. Wall 328 includes include circular porthole 330 that is normally covered by circular plate 332. When plate 332 is removed from porthole 330, the components within housing 302 can be serviced through the porthole. The ceiling of housing 302 carries position sensor arrangement 334 for controlling motor 322 that drives conveyor rollers 320.

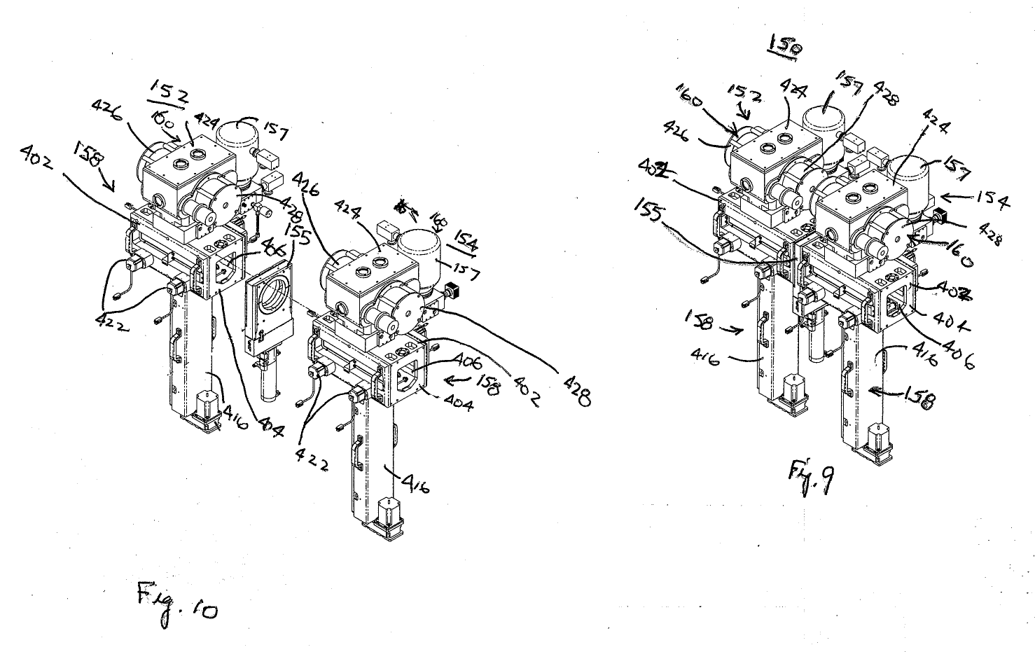

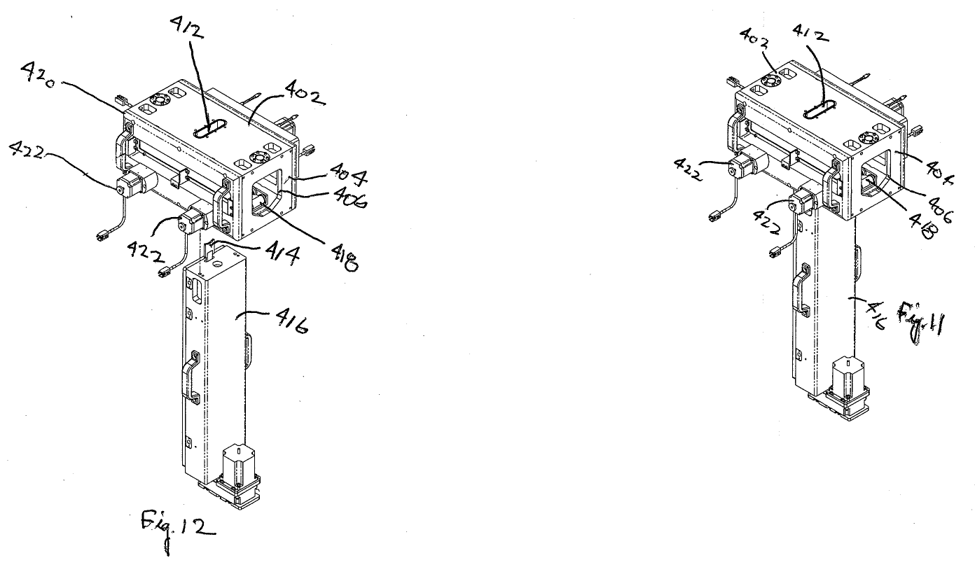

Reference is now made to FIGS. 9-12, wherein FIGS. 9 and 10 are respectively perspective and semi-exploded perspective views of process module 150, and FIGS. 11 and 12 are respectively perspective and semi-exploded perspective views of transport segment 158 of one of the sections 152 or 154 of process module 150. Because sections 152 and 154 are essentially the same, only section 152 is described.

Section 152 includes metal housing 402, shaped as a right parallelepiped including two parallel walls 404 (only one of which is illustrated). Walls 404 include aligned apertures 406 through which cassettes 102 can pass. Parallel walls 404 are at right angles to walls 408 (only one of which is illustrated), having a length between walls 404 that is slightly greater than the length of two longitudinally aligned cassettes. Apertures 406 in section 152 are aligned with corresponding apertures in section 154 and with aperture 408 of solenoid activated gate valve 155, which is the same as gate valve 130, FIG. 4. Gate valve 155 is between adjacent faces 404 of sections 152 and 154 so that opposite faces of valve 155 abut the adjacent faces 404 of sections 152 and 154.

The floor and ceiling 410 of housing 402 include aligned elongated slots 412, each having a longitudinal axis parallel to walls 404 (the floor of housing 402 and the slot in the floor are not illustrated). The slot in the floor of housing 402 is dimensioned and positioned to enable solenoid activated lift blade 414, which is carried by lift blade assembly 416, to extend through the floor slot to engage and lift a magnetic hard disk in the cassette in housing 402 from that cassette into process segment 160. Slot 412 in ceiling 410 is dimensioned and positioned to enable the magnetic hard disk, which has been lifted by blade 414 from the cassette in transport segment 158, to be driven into process segment 160.

Motor driven roller conveyor 418 that propels cassettes through housing 402 between walls 404 and assists in moving the cassettes through openings 406 extends substantially through the length of the housing between walls 404. Conveyor 418, which consists of two sequential, longitudinally aligned portions, is carried by plate 420 in a manner similar to the way conveyor 320 is carried by plate 318. The two portions of conveyor 418 are separately driven by motors 422 carried by plate 420.

Process segment 160, fixedly mounted on the ceiling of housing 402, includes coating chamber 424 and vapor sources 426 and 428 that are fixedly mounted on opposite exterior faces of the coating chamber. Vapor sources 426 and 428 simultaneously supply lube vapor to opposite parallel faces of the magnetic hard disk that has been lifted by blade 414 through slot 412 into coating chamber 424. Process segment 160 includes a sensor arrangement that determines when a particular magnetic hard disk has received an adequate amount of vapor lube, to derive a signal. The signal controls the solenoid drive for lift blade 414, to cause the lift blade to be lowered to remove the processed magnetic hard disk from coating chamber 424. Because separate magnetic disks are typically simultaneously in the coating chambers 424 of sections 152 and 154, four magnetic disks faces are typically coated with lube at the same time.

While there has been described and illustrated a specific embodiment of the invention, it will be clear that variations in the details of the embodiment specifically illustrated and described may be made without departing from the true spirit and scope of the invention as defined in the appended claims. For example, the U shape of facility 100 is not always necessary, and it is not always necessary to employ load locks, unload locks, buffer modules and process modules having the capability of handling two cassettes at a time. However, the U shape facility and the use of load locks, unload locks, buffer modules and process modules having the capability of handling two cassettes at a time provide an optimum compromise with regard to minimizing footprint area while providing high throughput speed.

What is claimed is:

1. A facility for depositing lubricant coatings on hard magnetic disks that are adapted to be loaded in cassettes, the facility comprising an arrangement for conveying the cassettes through a path including: (a) a vacuum load lock, (b) a vacuum unload lock, and (c) a vacuum process module for depositing lubricant vapor onto the hard magnetic disks, the process module being arranged for enabling the deposited lubricant vapor to form a lubricant coating on the hard magnetic disks, the process module being between the vacuum load and unload locks, the path being arranged for turning the cassettes approximately 90° at least once.

2. The facility of claim 1 wherein at least one of the vacuum load and unload locks is the part of the path arranged for turning the cassettes 90°.

3. The facility of claim 2 wherein the load lock includes first and second valves respectively at entrance and exit regions of the load lock, the unload lock includes third and fourth valves respectively at entrance and exit regions of the unload lock, the load lock being arranged for enabling a plurality of the cassettes to be simultaneously between the first and second valves, the unload lock being arranged for enabling a plurality of the cassettes to be simultaneously between the third and fourth valves.

4. The facility of claim 3 wherein the path includes a plurality of process modules arranged for simultaneously depositing lubricant vapor onto a plurality of hard magnetic disks initially loaded into a plurality of the cassettes.

5. The facility of claim 4 wherein the path includes a plurality of buffer modules between the second valve of the load lock and a first of the process modules, the plurality of buffer modules being arranged for enabling a plurality of the cassettes to be simultaneously in the plurality of buffer modules.

6. The facility of claim 2 wherein the load and unload locks are both arranged for turning the cassettes approximately 90°.

7. The facility of claim 2 wherein the load lock is arranged for turning the cassettes approximate 90°.

8. The facility of claim 2 wherein the unload lock is arranged for turning the cassettes approximate 90°.

9. The facility of claim 1 wherein the load lock includes first and second valves respectively at entrance and exit regions of the load lock, the path further including a plurality of buffer modules between the second valve of the load lock and the process module, the plurality of buffer modules being arranged for enabling a plurality of the cassettes to be simultaneously in the plurality of buffer modules.

10. The facility of claim 1 wherein the path includes a plurality of process modules arranged for simultaneously depositing lubricant vapor onto a plurality of hard magnetic disks initially loaded into a plurality of the cassettes.

11. A facility for depositing lubricant coatings on hard magnetic disks that are adapted to be loaded in cassettes, the facility comprising an arrangement for conveying the cassettes through a path including: (a) a vacuum load lock, (b) a vacuum unload lock, and (c) a plurality of vacuum process modules arranged for substantially simultaneously depositing lubricant vapor onto a plurality of hard magnetic disks initially loaded into a plurality of the cassettes, the plurality of process modules being arranged for enabling the deposited lubricant vapor to form a lubricant coating on the hard magnetic disks, the process modules being between the vacuum load and unload locks.

12. A facility for depositing lubricant coatings on hard magnetic disks that are adapted to be loaded in cassettes, the facility comprising an arrangement for conveying the cassettes through a path including: (a) a vacuum load lock, (b) a vacuum unload lock, and (c) a vacuum process module for depositing lubricant vapor onto the hard magnetic disks, the process module being arranged for enabling the deposited lubricant vapor to form a lubricant coating on the hard magnetic disks, the process module being between the vacuum load and unload locks, the load lock including first and second valves respectively at entrance and exit regions of the load lock, the unload lock including third and fourth valves respectively at entrance and exit regions of the unload lock, at least one of the load and unload locks being arranged for enabling a plurality of the cassettes to be simultaneously between the valves thereof.

13. The facility of claim 12 wherein both the load and unload locks are arranged for enabling a plurality of the cassettes to be simultaneously between the valves thereof.

14. The facility of claim 12 wherein the load lock is arranged for enabling a plurality of the cassettes to be simultaneously between the valves thereof.

15. The facility of claim 12 wherein the unload lock is arranged for enabling a plurality of the cassettes to be simultaneously between the valves thereof.

16. The facility of claim 12 wherein the path further includes a buffer region between the exit region of the load lock and the process module, the buffer region being arranged for enabling a plurality of the cassettes to be simultaneously therein.

17. A facility for depositing lubricant coatings on hard magnetic disks that are adapted to be loaded in cassettes, the facility comprising an arrangement for conveying the cassettes through a path including: (a) a vacuum load lock, (b) a vacuum unload lock, (c) a vacuum process module for depositing lubricant vapor onto the hard magnetic disks, and (d) a buffer region; the process module being arranged for enabling the deposited lubricant vapor to form a lubricant coating on the hard magnetic disks, the process module being between the vacuum load and unload locks; the load lock including first and second valves respectively at entrance and exit regions of the load lock; the unload lock including third and fourth valves respectively at entrance and exit regions of the unload lock; the buffer region being between the exit region of the load lock and the process module, the buffer region being arranged for enabling a plurality of the cassettes to be simultaneously therein.

18. The facility of claim 17 wherein the buffer region is arranged for enabling two and no more than two of the cassettes to be simultaneously therein, the load lock includes first and second valves respectively at entrance and exit regions of the load lock, the unload lock includes third and fourth valves respectively at entrance and exit regions of the unload lock, the load lock being arranged for enabling two and no more than two cassettes to be simultaneously between the first and second valves, the unload lock being arranged for enabling two and no more than two cassettes to be simultaneously between the third and fourth valves, the vacuum load and unload locks being arranged for turning the cassettes approximately 90°, and the facility includes two and not more than two process modules arranged for simultaneously depositing lubricant vapor onto two and not more than two hard magnetic disks.

19. The facility of claim 18 wherein the facility, in plan view, is shaped approximately as a U having first and second parallel legs connected together by a base that is at right angles to the first and second parallel legs, the first leg including the load lock, the second leg including the unload lock, and the base including the buffer region and the two process modules, the spacing between the legs and the lengths of the legs being sufficient to form an operator area within the U for enabling an operator (a) to load cassettes with hard magnetic disks therein onto the conveyor arrangement at a portion of the first leg in proximity to the end of the first leg remote from the base, and (b) to remove cassettes with hard magnetic disks that have been coated in the process modules from the conveyor arrangement at a portion of the second leg in proximity to the end of the second leg remote from the base.

20. The facility of claim 19 wherein the legs have substantially the same length.
